(19) United States
(12) Patent Application Publication
(10) Pub. No.: US 2026/0090081 A1
(43) Pub. Date: Mar. 26, 2026

(54) Semiconductor Device and Method of Fabricating the Same

(71) Applicant: UNITED MICROELECTRONICS CORP., Hsin-Chu City (TW)

(72) Inventors: Yung-Fang Yang, Chiayi City (TW); Ming-Hua Tsai, Tainan City (TW); Chin-Chia Kuo, Tainan City (TW); Chun-Lin Chen, Tainan City (TW); Chun-Wen Cheng, New Taipei City (TW); Ming-Hsiang Tu, Tainan City (TW); Ya-Hsin Huang, Tainan City (TW)

(73) Assignee: UNITED MICROELECTRONICS CORP., Hsin-Chu City (TW)

(21) Appl. No.: 18/926,344

(22) Filed: Oct. 25, 2024

(30) Foreign Application Priority Data
Sep. 24, 2024 (TW) 113136193

(51) Int. Cl. H01L 27/088; H01L 29/49; H01L 29/66; H01L 29/78

(52) U.S. Cl. CPC H10D 84/834; H10D 30/024; H10D 30/62; H10D 64/661; H10D 84/0128; H10D 84/0158

(57) ABSTRACT

A semiconductor device and method of fabricating the same, includes a substrate, a recess, a first gate dielectric layer, a first gate electrode, and a first plug. The substrate includes a medium-voltage region and a low-voltage region. The recess is disposed in the substrate, within the medium-voltage region. The first gate dielectric layer is disposed on a plane of the recess. The first gate electrode is disposed on the first gate dielectric layer. The first plug is disposed on the first gate electrode and on the recess, and the first plug is electrically connected the first gate electrode.

### BACKGROUND OF THE INVENTION

### 1. Field of the Invention

The present disclosure relates generally to a semiconductor device and a method of fabricating the same, and more particularly to a semiconductor device including a medium-voltage (MV) component, and a method of fabricating the same.

### 2. Description of the Prior Art

According to the current semiconductor technology, it is able to integrate control circuits, memories, low-voltage operating circuits, and high-voltage operating circuits and components on a single chip together, thereby reducing costs and improving operating efficiency. High-voltage components such as vertical double-diffusion metal-oxide-semiconductor (VDMOS), insulated gate bipolar transistor (IGBT), lateral-diffusion metal-oxide-semiconductor (LDMOS), etc. fabricated in a chip are used in various applications due to their better power switching efficiency. Those skilled in the art should know that the aforementioned high-voltage components are often required to withstand higher breakdown voltages and operate at lower resistance values.

In addition, as the size of semiconductor components becomes smaller and smaller, there are many improvements in the process steps of forming transistors to fabricate transistors with small volume and high quality. For example, non-planar field effect transistors, such as fin field-effect transistors (FinFETs), have replaced planar field effect transistors as the current mainstream development trend. However, as the size of devices continues to decrease, it becomes more difficult to dispose high-voltage components and fin field-effect transistors on the same semiconductor device together, and the processes of forming the semiconductor device also faces many limitations and challenges.

### SUMMARY OF THE INVENTION

An object of the present disclosure is to provide a semiconductor device, where a plug electrically connected to a medium-voltage (MV) component is disposed on a plane of a substrate recess, simultaneously overlapping a gate electrode and a diffusion region disposed underneath. Therefore, the semiconductor device of the present disclosure is allowable to gain a better flatness and a more compact installation, to improve the device functions and the performances.

An object of the present disclosure is to provide a method of fabricating a semiconductor device, in which a plug electrically connected to a medium-voltage (MV) component, is formed on a plane of a substrate recess, with the plug being simultaneously overlapped with a gate electrode and a diffusion region underneath. Therefore, the semiconductor device fabricated accordingly in the present disclosure is allowable to gain a better flatness and a more compact installation, to improve the device functions and the performances.

To achieve the aforementioned objects, the present disclosure provides a semiconductor device including a substrate, a recess, a first gate dielectric layer, a first gate electrode, and a first plug. The substrate has a medium-voltage region and a low-voltage region. The recess is disposed in the substrate, within the medium-voltage region. The first gate dielectric layer is disposed on a plane of the recess. The first gate electrode is disposed on the first gate dielectric layer. The first plug is disposed on the first gate electrode and on the plane of the recess, with the first plug being electrically connected to the first gate electrode.

To achieve the aforementioned objects, the present disclosure provides a method of fabricating a semiconductor device including the following steps. A substrate is provided with the substrate having a medium-voltage region and a low-voltage region. A recess is formed in the substrate, within the medium-voltage region. A first gate dielectric layer is formed on a plane of the recess. A first gate electrode is formed on the first gate dielectric layer. A first plug is formed on the first gate electrode, and on the plane of the recess, with the first plug being electrically connected to the first gate electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 illustrate schematic diagrams of a semiconductor device according to a first embodiment of the present disclosure, in which:

FIG. 1 is a schematic top view of a semiconductor device according to the first embodiment of the present disclosure; and

FIG. 2 is a schematic cross-sectional view taken along a cross line A-A′ in FIG. 1.

FIG. 3 to FIG. 6 illustrate schematic diagrams of a method of fabricating a semiconductor device according to a first embodiment of the present disclosure, in which:

FIG. 3 is a schematic cross-sectional view of a semiconductor device after forming fin-shaped structures;

FIG. 4 is a schematic cross-sectional view of a semiconductor device after forming a recess;

FIG. 5 is a schematic cross-sectional view of a semiconductor device after forming a gate dielectric layer; and

FIG. 6 is a schematic cross-sectional view of a semiconductor device after forming a gate electrode.

FIG. 7 to FIG. 8 illustrate schematic diagrams of a semiconductor device according to a second embodiment of the present disclosure, in which:

FIG. 7 is a schematic top view of a semiconductor device according to the second embodiment of the present disclosure; and

FIG. 8 is a schematic cross-sectional view taken along a cross line A-A′ in FIG. 7.

FIG. 9 illustrates a schematic diagram of a semiconductor device according to a three embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

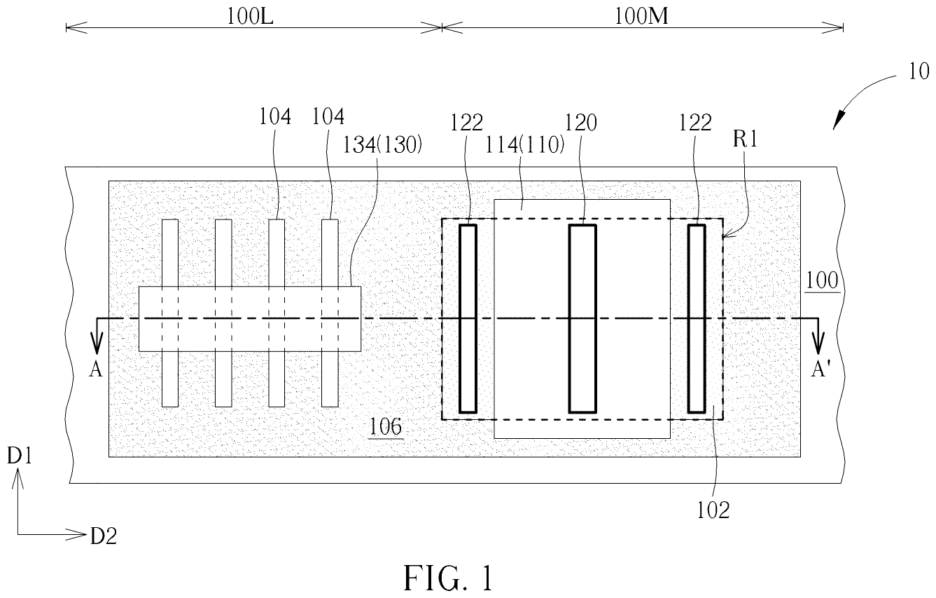

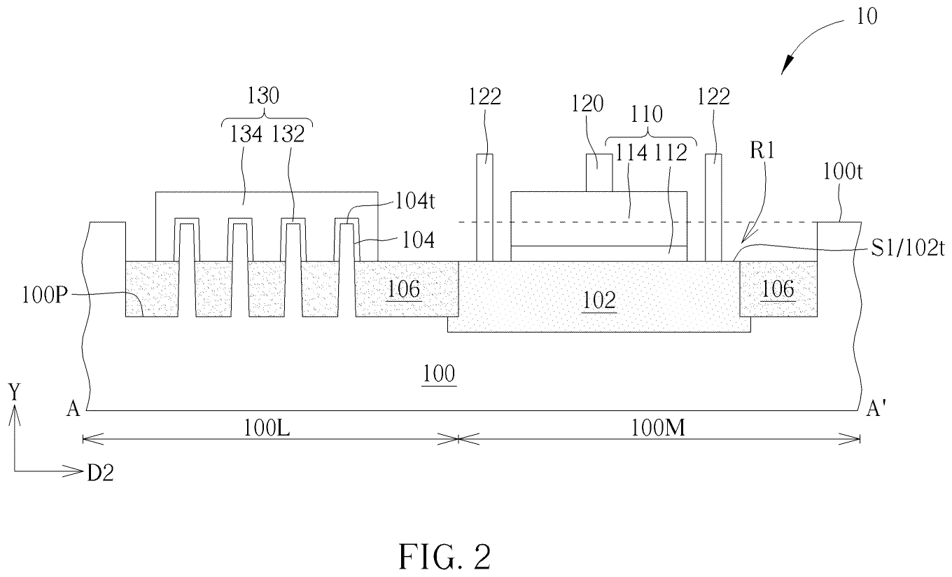

Please refer to FIG. 1 to FIG. 2, respectively illustrating a schematic top view and a schematic cross-sectional view of a semiconductor device 10 according to the first embodiment of the present disclosure. The semiconductor device 10 includes a substrate 100, a recess R1, a first gate dielectric layer 112, a first gate electrode 114, and a first plug 120. The substrate 100 for example includes a silicon substrate, an epitaxial silicon substrate, a silicon-containing substrate, or a silicon-on-insulator (SOI) substrate, but not limited thereto. The substrate 100 at least includes a medium-voltage (MV) region 100M and a low-voltage (LV) region 100L defined thereon. The medium-voltage region 100M may be used for arranging a planar transistor, and the low-voltage region 100L may be used for arranging a fin-shaped transistor, but not limited thereto. In one embodiment, the medium-voltage region 100M and the low-voltage region 100L are disposed for example adjacent to each other, as shown in FIG. 1 and FIG. 2, with two regions being isolated from each other through a shallow trench isolation 106 disposed within the substrate 100. In another embodiment, another region (not shown in the drawings) such as a high-voltage (HV) region may be further defined on the substrate 100, for arranging another planar transistor.

The recess R1 is disposed in the substrate 100 within the medium-voltage region 100M, for example being a sunken space recessed downwardly from a top surface 100t of the substrate 100, and the recess R1 includes a plane S1. The first gate dielectric layer 112 and the first gate electrode 114 are sequentially disposed on the plane S1 of the recess R1, with the first gate electrode 114 being disposed on the first gate dielectric layer 112. In one embodiment, the first gate electrode 114 for example includes a polysilicon gate electrode or a metal gate electrode, such that, the first gate dielectric layer 112 and the first gate electrode 114 stacked in sequence on the plane S1 will together become a gate structure 110, thereby next forming a medium-voltage transistor suitable for the required medium-voltage operation, after in combination with other suitable components. It is noted that, the first plug 120 is disposed on the first gate electrode 114, to electrically connect to the first gate electrode 114. The first plug 120 is disposed over the recess R1 in a vertical direction Y, right above the plane S1 of the recess R1, to completely overlap with the first gate electrode 114 thereby, as shown in FIG. 1 and FIG. 2. In other words, as being viewed from a top view as shown in FIG. 1, the first plug 120 is completely disposed within the extending area of the recess R1, instead of further extending over the shallow trench isolation 106. Accordingly, the first plug 120 is allowable to gain a better flatness, as well as a more compact installation, so as to improve the device function and the performance of the semiconductor device 10 thereby.

Further in view of FIG. 1 and FIG. 2, the semiconductor device 10 further includes a diffusion region 102 disposed in the substrate 100, within the medium-voltage region 100M, and two second plugs 122. The diffusion region 102 for example extends downwardly from the plane S1 of the recess R1 into the substrate 100, and which includes a proper dopant such as a P-type dopant or a N-type dopant, with the diffusion region 102 serving as a P-type doped well or a N-type doped well accordingly. The two second plugs 122 are disposed on the plane S1 of the recess R1, namely on a top surface 102t of the diffusion region 102, at two opposite sides of the first plug 120 respectively, to electrically connect to two source/drain regions (not shown in the drawings) disposed in the diffusion region 102. The top surface 102t of the diffusion region 102, namely the plane S1 of the recess R1, is lower than the top surface 100t of the substrate 100, as shown in FIG. 2. On the other hand, the first gate electrode 114, the first plug 120, and each of the two second plug 122 are all parallelly extended in the same direction D1, with the first gate electrode 114, the first plug 120, and each of the two second plug 122 being sequentially arranged in a direction D2 which is perpendicular to the direction D1. That is, the first gate electrode 114, the first plug 120, and each of the two second plugs 122 are respectively presented in a rectangular structure as shown in FIG. 1, but is not limited thereto. The first plug 120 is disposed completely within the extending area of the first gate electrode 114, and/or the diffusion region 102 disposed underneath, so that, the first plug 120 will therefore obtain a more compact installation.

The semiconductor device 10 further includes a plurality of fin-shaped structures 104, a second gate dielectric layer 132, and a second gate electrode 134 disposed within the low-voltage region 100L. The plurality of fin-shaped structures 104 is for example disposed on a plane 100P of the substrate 100, with the fin-shaped structures 104 being partially covered by the shallow trench isolation 106, and being partially protruded from the surface of the shallow trench isolation 106. A top surface 104t of each of the fin-shaped structures 104 is coplanar with the top surface 100t of the substrate 100, and is higher than the plane S1 of the recess R1, as shown in FIG. 2. The second gate dielectric layer 132 and the second gate electrode 134 are sequentially disposed on the fin-shaped structures 104 and the surface of the shallow trench isolation 106. Precisely speaking, the second gate dielectric layer 132 conformally overlays the portion of the fin-shaped structures 104 which are protruded from the shallow trench isolation 106, and the second gate electrode 134 is disposed on the second gate dielectric layer 132. In one embodiment, the second gate electrode 134 for example includes a polysilicon gate electrode or a metal gate electrode, such that, the second gate dielectric layer 132 and the second gate electrode 134 stacked in sequence on the fin-shaped structures 104 will together become a gate structure 130, thereby next forming a low-voltage transistor suitable for the required low-voltage operation, after in combination with other suitable components.

Through these arrangements, the semiconductor device 10 therefore includes the gate structure 110 disposed within the medium-voltage region 100M and the gate structure 130 disposed within the low-voltage region 100L, with the gate structure 110 within the medium-voltage region 100M serving as a medium-voltage component for a required medium-voltage operation, and with the gate structure 130 within the low-voltage region 100L serving as a low-voltage component for a required low-voltage operation. The medium-voltage component may refer to semiconductor transistors with an initial voltage between 5 volts and 10 volts, and the low-voltage component may refer to semiconductor transistors with an initial voltage between 0.5 volt and 1 volt, but not limited thereto. It is noted that, according to the semiconductor device 10 of the present embodiment, the recess R1, being sunken from the top surface 100t of the substrate 100, is disposed in the medium-voltage region 100M, and the gate structure 110 and the second plugs 122 are disposed on the plane S1 of the recess R1, so as to effectively improve the possible height difference between the gate structure 110 of the medium-voltage component and the gate structure 130 of the low-voltage component. In addition, the first plug 120 electrically connected to the medium-voltage component is further disposed on the plane S1 of the recess R1, within the semiconductor device 10, so that, the first plug 120 will therefore gain a better flatness, improving the structural stability and the operation. The location of the first plug 120 simultaneously overlaps the first gate electrode 114 and the diffusion region 102 underneath, in the vertical direction Y, so that, the installation of the first plug 120 will be more compacted, thereby improving the overall functions and the performance of the semiconductor device 10.

In order to make those having ordinary skills in the art easily understand the semiconductor device 10 according to the present disclosure, a fabricating method of the semiconductor device 10 according to the present disclosure will be further described as follows.

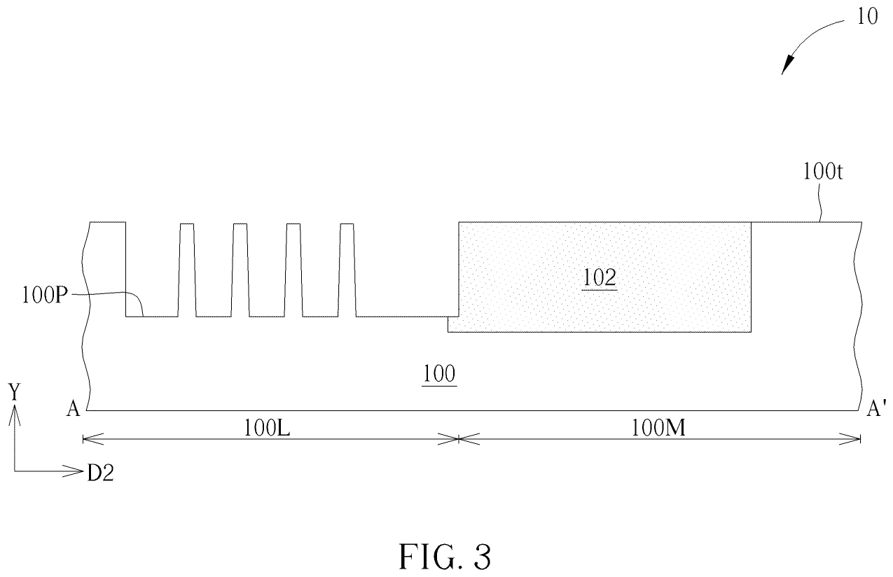

Please refer to FIG. 3 to FIG. 6, which are schematic diagrams illustrating a method of fabricating the semiconductor device 10 according to a preferably embodiment of the present disclosure. Firstly, as shown in FIG. 3, the substrate 100 is provided, and the substrate 100 includes the medium-voltage region 100M and the low-voltage region 100L adjacent to each other, being defined on the substrate 100. Then, the fin-shaped structures 104 are formed within the low-voltage region 100L. In one embodiment, the formation of the fin-shaped structures 104 includes but not limited to the following step. Firstly, a bulk silicon substrate (not shown in the drawings) is provided, and a self-aligned double patterning process (SADP) or a self-aligned reverse patterning process (SARP) is performed on a region of the bulk silicon substrate where the low-voltage region 100L is predicted to be formed in, to partially remove the region of the bulk silicon substrate to form the plane 100P and the fin-shaped structures 104 protruded from the plane 100P. Then, the top surface 104t of each of the fin-shaped structures 104 is coplanar with the top surface 100t of the substrate 100, and the plane 100P is lower than the top surface 100t of the substrate 100, as shown in FIG. 3. Furthermore, before forming the fin-shaped structures 104, a diffusion region 102a as shown in FIG. 3 may be previously formed in another region of the bulk silicon substrate where the medium-voltage region 100M is predicted to be formed in. Otherwise, in another embodiment, the diffusion region 102a as shown in FIG. 3 may also be formed in the substrate 100 within the medium-voltage region 100M, after forming the fin-shaped structures 104. The diffusion region 102a for example extends downwardly from the top surface 100t of the substrate 100 into the substrate 100, and which includes a suitable dopant such as a P-type dopant or a N-type dopant, but not limited thereto. In one embodiment, a depth of the diffusion region 102a is preferably greater than a depth of the shallow trench isolation 106, as shown in FIG. 3, but not limited thereto.

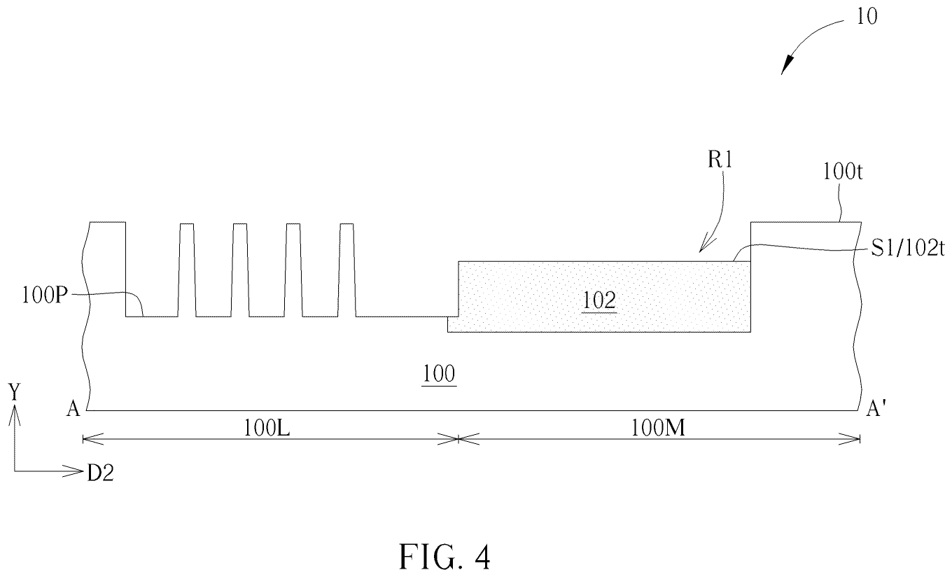

As shown in FIG. 4, an etching process is performed on the medium-voltage region 100M of the substrate 100 through a mask layer (not shown in the drawings) overlaying the low-voltage region 100L of the substrate 100, to partially remove the substrate 100 to form the recess R1, and also to form the diffusion region 102 at the same time. Precisely speaking, the recess R1 is a sunken space being etched downwardly from the top surface 100t of the substrate 100, to expose the top surface 102t of the diffusion region 102. Through these performance, the recess R1 will therefore form the plane S1 with a relative better flatness, with the plane S1 being the top surface 102t of the diffusion region 102, and with the plane S1 being lower than the top surface 104t of the fin-shaped structures 104 and/or the top surface 100t of the substrate 100. Then, the mask layer is completely removed.

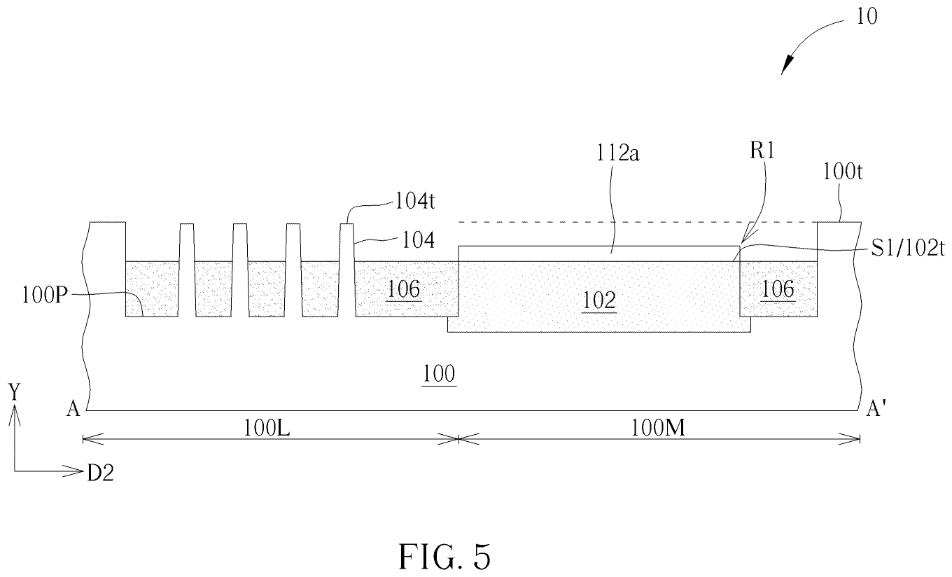

As shown in FIG. 5, a patterning process is performed on the substrate 100 through another mask layer (not shown in the drawings), to form at least one shallow trench (not shown in the drawings) in the substrate 100, followed by sequentially performing a deposition process and an etching back process, to form the shallow trench isolation 106. In one embodiment, the top surface of the shallow trench isolation 106 is for example leveled with the plane S1 (namely, the top surface 102t of the diffusion region 102) of the recess R1, but not limited thereto. Accordingly, each of the fin-shaped structures 104 is partially covered by the shallow trench isolation 106, so that, a rest portion of each of the fin-shaped structures 104 is protruded from the top surface of the shallow trench isolation 106. Then, the another mask layer is completely removed. Next, further in view of FIG. 5, a deposition process is performed on the plane S1 of the recess R1, to form a first gate dielectric material layer 112a on the plane S1. In one embodiment, the first gate dielectric material layer 112a for example includes a dielectric material like silicon oxide, or silicon oxynitride, but not limited thereto. However, people skilled in the art should fully realize that the formations of the fin-shaped structures 104, the shallow trench isolation 106, and the recess R1 may not be carried out in the aforementioned order, and which may be performed in another order due to practical requirements. In another embodiment, the recess R1 may be formed at first, followed by forming the fin-shaped structures 104 and the shallow trench isolation 106.

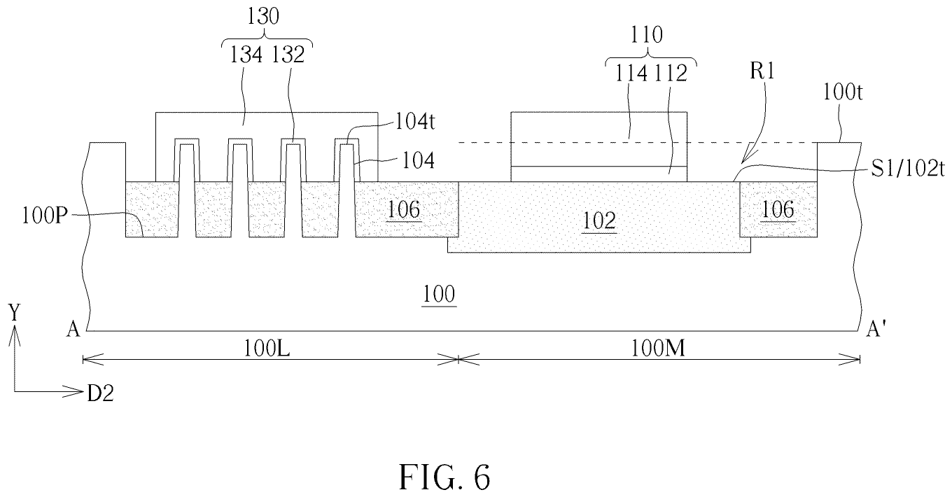

As shown in FIG. 6, a gate material layer (not shown in the drawings) is formed on the first gate dielectric material layer 112a, and a patterning process is performed on the gate material layer and the first gate dielectric material layer 112a, to form the first gate dielectric layer 112 and the first gate electrode 114 stacked in sequence on the plane S1 of the recess R1. Then, the first gate dielectric layer 112 and the first gate electrode 114 will therefore form the gate structure 110, and the gate structure 110 may be served as the medium-voltage transistor in combination with other suitable components, for carrying out the required medium-voltage operation. On the other hand, further in view of FIG. 6, after forming the gate structure 110, a deposition process and a patterning process are next performed on the substrate 100, within the low-voltage region 100L, to form the second gate dielectric layer 132 and the second gate electrode 134 stacked in sequence on the fin-shaped structures 104 and the top surface of the shallow trench isolation 106. Then, the second gate dielectric layer 132 and the second gate electrode 134 will therefore form the gate structure 130, and the gate structure 130 may be served as the low-voltage transistor in combination with other suitable components, for carrying out the required low-voltage operation. In one embodiment, the first gate electrode 114 and/or the second gate electrode 134 for example include a polysilicon gate electrode or a metal gate electrode, but not limited thereto. People skilled in the art should fully realize that the formations of the gate structures 110, 130 may not be carried out in the aforementioned order, and which may be performed in other order due to practical requirements. In another embodiment, the first gate electrode 114 and the second gate electrode 134 are simultaneously formed after forming the first gate dielectric layer 112 and second gate dielectric layer 132, and a replacement metal gate (RMG) process is next performed on the first gate electrode 114 and the second gate electrode 134, to form two metal gate structures.

Following these, the first plug 120 electrically connected to the first gate electrode 114 within the medium-voltage region 100M, and the two second plugs 122 each electrically connected to the source/drain region (not shown in the drawings) within the diffusion region 102, are formed on the substrate, and the fabrication of the semiconductor device 10 as shown in FIG. 1 and FIG. 2 is accomplished accordingly. It is noted that, the first plug 120 is formed on the plane S1 in the vertical direction “Y”, such that the first plug 120 will obtain a better flatness, so as to gain a better stability and a better operation thereby. Furthermore, since the first plug 120 is formed to completely overlap the first gate electrode 114 and the diffusion region 102 underneath, without further extending over the shallow trench isolation 106 adjacent to the diffusion region 102, the poor height difference issue possibly caused by various materials and flatness among different regions will be effectively improved. In this way, the installation of the first plug 120 will become more compact, so as to improving the device function and the performance of the semiconductor device 10. According to the method of fabricating the semiconductor device 10 in the present embodiment, the gate structure 110 and the gate structure 130 are respectively formed within various regions (including the medium-voltage region 100M and the low-voltage region 100L) of the substrate 100, such that, the gate structure 110 within the medium-voltage region 100M will further form a medium-voltage component for carrying the required medium-voltage operation, and the gate structure 130 within the low-voltage region 100L will further form a low-voltage component for carrying the required low-voltage operation. That is, the formations of the low-voltage component and the medium-voltage component may be effectively integrated with each other through the fabricating method of the present embodiment, thereby forming a plug structure having a better flatness and a more compact installation. Then, the semiconductor device 10 formed accordingly in the present embodiment will therefore gain the improved function and performance.

Those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

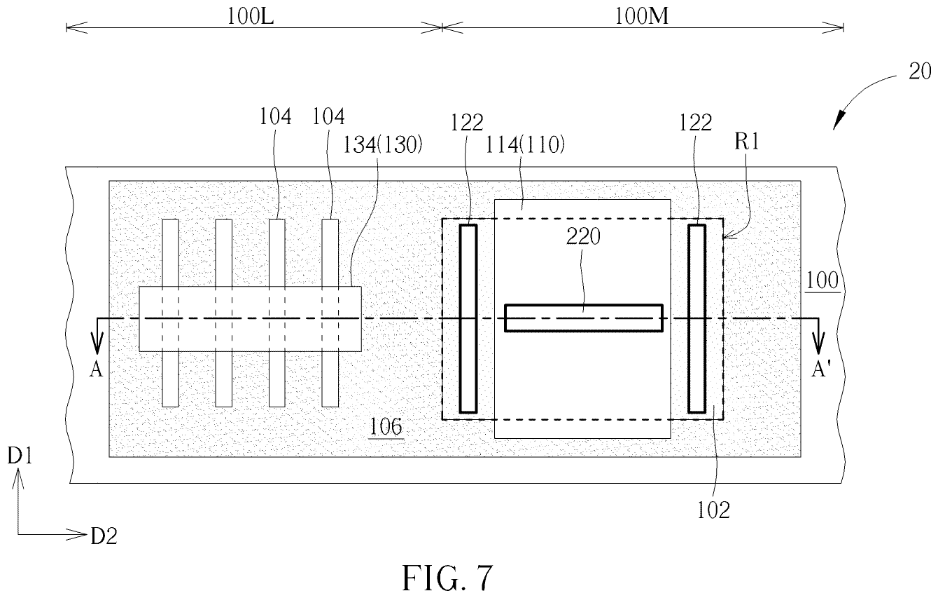

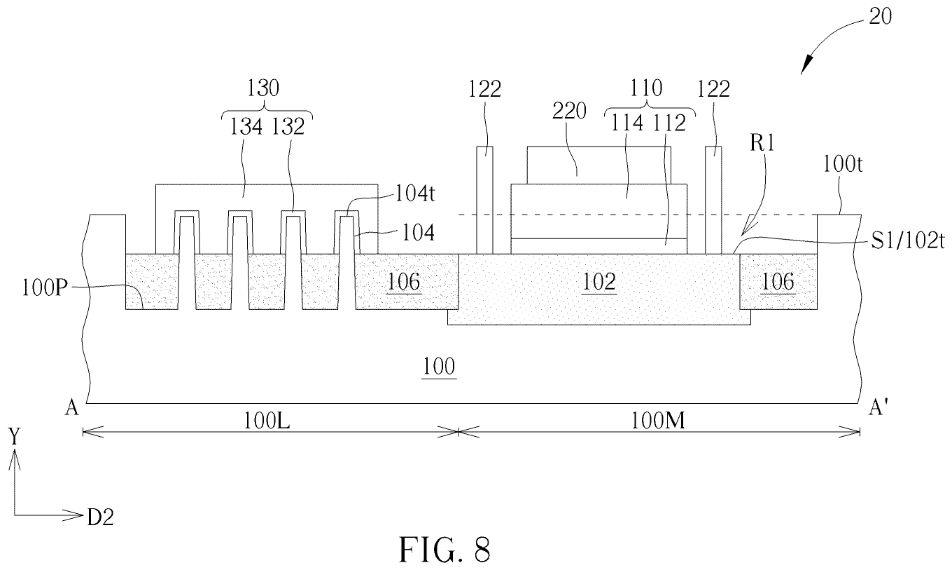

Please refer to FIG. 7 and FIG. 8, respectively illustrating a schematic top view and a schematic cross-sectional view of a semiconductor device 20 according to the second embodiment of the present disclosure. The structure of the semiconductor device 20 in the present embodiment is substantially the same as that of the aforementioned semiconductor device 10, including the substrate 100, the recess R1, the first gate dielectric layer 112 and the first gate electrode 114, and all the similarities will not be redundantly described hereinafter. The difference between the semiconductor device 20 in the present embodiment and the semiconductor device 10 in the aforementioned embodiment is mainly in that the first gate electrode 114 and the first plug 220 are respectively extended along two directions D1, D2 which are perpendicular to each other.

Precisely speaking, as shown in FIG. 7 and FIG. 8, the first gate electrode 114 and each of the second plugs 122 may respectively extend in the direction D1, with each of the first gate electrode 114 and the two second plugs 122 being sequentially arranged in the direction D2 perpendicular to the direction D1. The first plug 220 extends in the direction D2, such that, the extending direction D2 of the first plug 220 is vertical to the extending direction D1 of the first gate electrode 114. It is noted that, the first plug 220 of the present embodiment is also disposed on the plane S1 of the recess R1 in the vertical direction Y, with the first plug 220 completely overlapping the first gate electrode 114 and the diffusion region 102 underneath, so that, the first plug 220 of the present embodiment will still obtain a better flatness and a more compact installation, to improve the device function and performance of the semiconductor device 20 thereby.

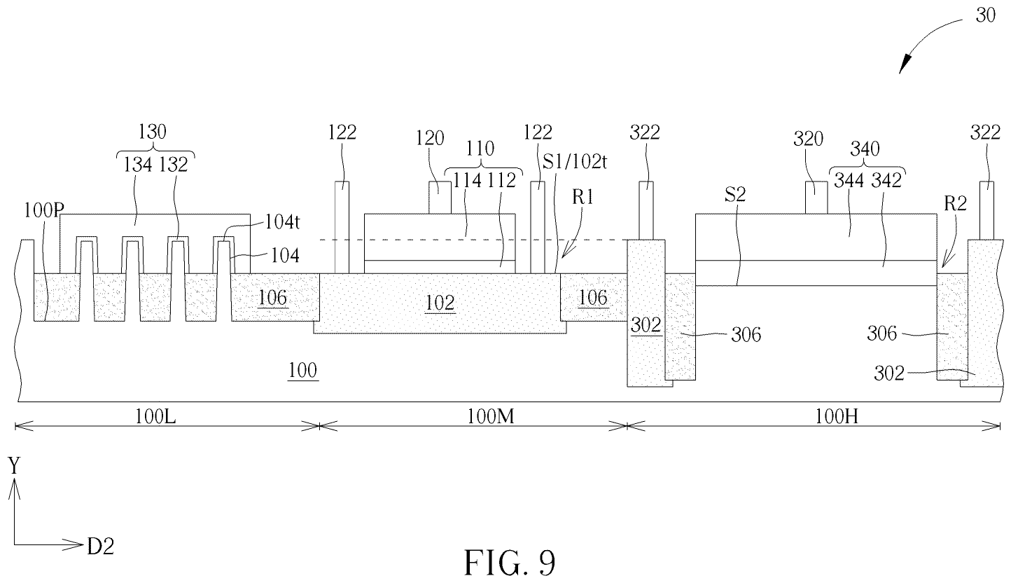

Please refer to FIG. 9, illustrating a schematic cross-sectional view of a semiconductor device 30 according to the third embodiment of the present disclosure. The structure of the semiconductor device 30 in the present embodiment is substantially the same as that of the aforementioned semiconductor device 10, including the substrate 100, the recess R1, the first gate dielectric layer 112, the first gate electrode 114 and the first plug 120, and all the similarities will not be redundantly described hereinafter. The difference between the semiconductor device 30 in the present embodiment and the semiconductor device 10 in the aforementioned embodiment is mainly in that the semiconductor device 30 further includes a high-voltage region 100H defined on the substrate 100, and at least one shallow trench isolation 306, a third gate dielectric layer 342, a third gate electrode 344, and a third plug 320 disposed within the high-voltage region 100H.

As shown in FIG. 9, the high-voltage region 100H is for example disposed at a side of the medium-voltage region 100M, for arranging a high-voltage component in the subsequent process, wherein the high-voltage component may refer to semiconductor transistors with an initial voltage between 10 volts and 20 volts, but not limited thereto. People skilled in the art should fully realize that the practical arrangement of the low-voltage region 100L, the medium-voltage region 100M and the high-voltage region 100H on the substrate 100 is not limited to which is shown in FIG. 9, and which may also be arranged in another order. The high-voltage region 100H also includes a recess R2 being sunken from the top surface 100t of the substrate 100, between two shallow trench isolations 306. The third gate dielectric layer 342 and the third gate electrode 344 are stacked in sequence on a plane S2 of the recess R2, so that, the third gate dielectric layer 342 and the third gate electrode 344 will together become a gate structure 340, thereby forming a high-voltage transistor suitable for the required high-voltage operation, after in combination with other suitable components. In a preferably embodiment, a thickness of the third gate dielectric layer 342 is greater than a thickness of the second gate dielectric layer 132, but not limited thereto.

Precisely speaking, the plane S2 of the recess R2 is preferably lower than the plane S1 of the recess R1, and is lower than the top surface 100t of the substrate 100, such that, the gate structure 340 subsequently formed on the plane S2 will obtain a top surface being leveled with the top surfaces of the gate structure 130 within the low-voltage region 100L and the gate structure 110 within the medium-voltage region 100M. That is, top surfaces of the third gate electrode 344, the second gate electrode 134, and the first gate electrode 114 are coplanar with each other. Also, the third plug 320 disposed on the third gate electrode 344 and electrically connected to the gate structure 340 is disposed on the plane S2 of the recess R2 in the vertical direction Y, to overlap with the third gate electrode 344 underneath. In other words, if being viewed from a top view (not shown in the drawings), the third plug 320 may be completely disposed within the extending area of the recess R2, instead of further extending over the shallow trench isolation 306 adjacent thereto. In this way, the third plug 320 is also allowable to gain a better flatness, as well as a more compact installation. On the other hand, the semiconductor device 30 further includes two doped regions 302 disposed in the substrate 100 within the high-voltage region 100H, and two fourth plugs 322 electrically connected to the two doped regions 302, respectively. The two doped regions 302 are respectively disposed at two opposite sides of the gate structure 340 in the direction D2, so that, the two shallow trench isolations 306 are respectively between a side of the gate structure 340 and one corresponding doped region 302. The two fourth plugs 322 are respectively disposed on the two doped regions 302, to electrically connect thereto. In one embodiment, the doped regions 302 for example includes a suitable dopant such as a P-type dopant or a N-type dopant, for serving as two source/drain regions of the high-voltage transistor thereby, but not limited thereto.

With these arrangements, the semiconductor device 30 of the present embodiment includes the gate structure 340 disposed within the high-voltage region 100H, the gate structure 110 disposed within the medium-voltage region 100M and the gate structure 130 disposed within the low-voltage region 100L, with the gate structure 340 within the high-voltage region 100H serving as a high-voltage component for the required high-voltage operation subsequently, with the gate structure 110 within the medium-voltage region 100M serving as a medium-voltage component for the required medium-voltage operation subsequently, and with the gate structure 130 within the low-voltage region 100L serving as a low-voltage component for the required low-voltage operation subsequently. It is noted that, according to the semiconductor device 30 of the present embodiment, the first plug 120 electrically connected to the medium-voltage component is disposed on the plane S1 of the recess R1, and the third plug 320 electrically connected to the high-voltage component is disposed on the plane S2 of the recess R2, so that, the first plug 120 and the third plug 320 will both gain a better flatness, to improve the structural stability and the operation, and to further improve the overall functions and performance of the semiconductor device 30.

Overall speaking, according to the semiconductor device and the method of fabricating the same, a plug structure electrically connected to the medium-voltage component is arranged on a plane of a substrate recess, to simultaneously overlap a gate electrode and a diffusion region disposed underneath, such that, the plug structure will therefore gain a better flatness and a more compact installation, so as to improve the overall function and the performance of the semiconductor device. In addition, the formation of the medium-voltage component of the present disclosure can be effectively integrated with the fabricating process of the low-voltage component within other regions, so as to form the plug structure having a better flatness and more compact installation, under a simplified process flow.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a medium-voltage region and a low-voltage region;
a recess disposed in the substrate, within the medium-voltage region;
a first gate dielectric layer disposed on a plane of the recess;
a first gate electrode, disposed on the first gate dielectric layer; and
a first plug disposed on the first gate electrode and on the plane of the recess, the first plug electrically connected the first gate electrode.

2. The semiconductor device according to claim 1, wherein the first gate electrode and the first plug are respectively extended along a same direction.

3. The semiconductor device according to claim 1, wherein the first gate electrode and the first plug are respectively extended along two different directions which are perpendicular to each other.

4. The semiconductor device according to claim 1, wherein first gate electrode comprises a polysilicon gate electrode or a metal gate electrode.

5. The semiconductor device according to claim 1, further
comprising:
a diffusion region disposed in the substrate, within the medium-voltage region; and
two second plugs respectively disposed at two opposite sides of the first plug, on a top surface of the diffusion region, wherein the top surface of the diffusion region is lower than a top surface of the substrate.

6. The semiconductor device according to claim 5, wherein, the two second plugs and the first gate electrode are respectively extended along a same direction.

7. The semiconductor device according to claim 5, wherein the plane of the recess is lower than the top surface of the substrate.

8. The semiconductor device according to claim 5, further comprising:
a plurality of fin-shaped structures disposed in the substrate, within the low-voltage region;
a second gate dielectric layer conformally disposed on the plurality of fin-shaped structures; and
a second gate electrode disposed on the second gate dielectric layer.

9. The semiconductor device according to claim 8, wherein a top surface of each of the plurality of fin-shaped structures is leveled with the top surface of the substrate.

10. The semiconductor device according to claim 8, wherein a top surface of each of the plurality of fin-shaped structures is higher than the plane of the recess.

11. The semiconductor device according to claim 8, wherein a top surface of the second gate electrode is level with a top surface of the first gate electrode.

12. A method of fabricating a semiconductor device, comprising:
providing a substrate having a medium-voltage region and a low-voltage region;
forming a recess in the substrate, within the medium-voltage region;
forming a first gate dielectric layer on a plane of the recess;
forming a first gate electrode on the first gate dielectric layer; and
forming a first plug on the first gate electrode, and on the plane of the recess, the first plug electrically connected the first gate electrode.

13. The method of fabricating the semiconductor device according to claim 12, wherein the first gate electrode and the first plug are respectively extended along a same direction.

14. The method of fabricating the semiconductor device according to claim 12, wherein the first gate electrode and the first plug are respectively extended along two different directions which are perpendicular to each other.

15. The method of fabricating the semiconductor device according to claim 12, further comprising:
forming a plurality of fin-shaped structures in the substrate, within the low-voltage region;
forming a second gate dielectric layer overlaying the plurality of fin-shaped structures; and
forming a second gate electrode on the second gate dielectric layer.

16. The method of fabricating the semiconductor device according to claim 15, wherein the recess is formed after forming the plurality of fin-shaped structures in the substrate, and further comprises:
partially removing a portion of the substrate within the medium-voltage region, to form the recess, wherein the plane of the recess is lower than a top surface of the substrate and a top surface of each of the plurality of the fin-shaped structures.

17. The method of fabricating the semiconductor device according to claim 16, further comprising:
forming a diffusion region in the substrate, within the medium-voltage region; and
forming two second plugs respectively at two opposite sides of the first plug, on a top surface of the diffusion region.

18. The method of fabricating the semiconductor device according to claim 17, wherein the top surface of the diffusion region is leveled with the top surface of the substrate.

19. The method of fabricating the semiconductor device according to claim 17, wherein the two second plugs and the first gate electrode are respectively extended along a same direction.
